(19) United States
(12) Patent Application Publication
(10) Pub. No.: US 2011/0139231 A1
(43) Pub. Date: Jun. 16, 2011

(54) BACK JUNCTION SOLAR CELL WITH SELECTIVE FRONT SURFACE FIELD

(76) Inventors: Daniel Meier, Norcross, GA (US); Ajeet Rohatgi, Marietta, GA (US); Vinodh Chandrasekaran, Suwanee, GA (US); Vijay Yelundur, Canton, GA (US); Preston Davis, Atlanta, GA (US); Ben Damiani, Atlanta, GA (US)

(21) Appl. No.: 12/868,240

(22) Filed: Aug. 25, 2010

(51) Int. Cl. H01L 31/0264; H01L 31/02; H01L 31/18

(52) U.S. Cl. 136/255; 136/252; 438/72; 257/E31.119

(57) ABSTRACT

Solar cells and methods for their manufacture are disclosed. An example method may include fabricating an n-type silicon substrate and introducing n-type dopant to one or more first and second regions of the substrate so that the second region is more heavily doped than the first region. The substrate may be subjected to a single high-temperature anneal cycle to form a selective front surface field layer. Oxygen may be introduced during the single anneal cycle to form in situ front and back passivating oxide layers. Fire-through of front and back contacts as well as metallization with contact connections may be performed in a single co-firing operation. The firing of the back contact may form a p⁺ emitter layer at the interface of the substrate and back contacts, thus forming a p-n junction at the interface of the emitter layer and the substrate. Associated solar cells are also provided.

### TECHNOLOGICAL FIELD

Embodiments of the present invention relate generally to solar cells. More particularly, embodiments of the present invention are directed to a back junction solar cell having a selective front surface field, and methods for its manufacture.

### BACKGROUND

In basic design, a solar cell is composed of a material such as a semiconductor substrate that absorbs energy from photons to generate electricity through the photovoltaic effect. When photons of light penetrate into the substrate, the energy is absorbed and an electron previously in a bound state is freed. The released electron and the previously occupied hole are known as charge carriers.

The substrate is generally doped with p-type and n-type impurities to create an electrical field inside the solar cell at the p-n junction. In order to use the free charge carriers to generate electricity, the electrons and holes must not recombine before they can be separated by the electrical field at the p-n junction. The electrons will then be collected by the electrical contacts on the n-type emitter layer and the holes will be collected by the electrical contacts on the p-type substrate. The charge carriers that do not recombine are available to power a load.

A common method for producing solar cells begins with a substrate doped to have p-type conductivity. An n-type dopant is introduced to the front surface of the substrate to form an n-type emitter layer on top of a p-type base layer. Typically, the substrate is moderately doped with dopant of p-type conductivity, while the emitter layer is heavily doped with dopant of n-type conductivity. As a result of forming the emitter layer, a p-n junction is formed near the illuminated surface of the substrate, that is, the front side of the substrate exposed to the light source when the solar cell is in use.

A major concern in the design of solar cells is the ability of the charge carriers to reach the electrical contacts prior to recombination. The distance a charge carrier is able to travel prior to recombination is sometimes known as charge carrier diffusion length. The charge carrier diffusion length may depend on various factors, such as the concentration of both dopant atoms and defects in the substrate. As the concentration of either dopant atoms or defects increases, the charge carrier diffusion length decreases. Thus, the diffusion length of holes in the heavily doped n-type emitter layer is much less than the diffusion length of electrons in the moderately doped p-type substrate. For this reason, the emitter layer is commonly referred to as a “dead layer” due to the fact that very few charge carriers created in the emitter layer are able to reach the p-n junction prior to recombination.

To lessen this problem, it is desirable to keep the emitter layer as thin and as lightly doped as possible. Creating a shallow emitter layer reduces the number of photons that are absorbed in the emitter layer. Even when photons are absorbed, a shallow emitter layer increases the likelihood that the generated charge carriers are able to reach the nearby p-n junction. Limitations exist, however, with respect to the thickness and dopant dose of the emitter layer. If the emitter layer is too shallow, the electrical contacts on the emitter layer may penetrate, thereby shorting, the p-n junction during contact formation. Similarly, if the dopant dose is too light, the contact resistance may be too high to form good contacts to the substrate. These issues are particularly relevant when contacts are formed by screen-printing, which requires high dopant concentration and contact firing.

To overcome these disadvantages, certain techniques have been suggested for forming a back junction solar cell. These cells suffer from their own disadvantages, however, such as low cell efficiencies, poor surface passivation, lack of sheet resistance uniformity, and the need for additional, costly manufacturing steps.

Therefore, there is a need in the art for producing back junction solar cells that overcome the above-mentioned and other disadvantages and deficiencies of previous technologies.

### BRIEF SUMMARY OF SOME EXAMPLES OF THE INVENTION

As used herein, embodiments in which a first element is described to be “overlying,” “over,” or “above” a second element may generally be taken to signify that the first element is closer to the primary illuminated surface or primary illumination source. For example, if a first element is said to be overlying a second element, the first element may be closer to the sun. Similarly, embodiments in which a first element is described to be “underlying,” “under,” and “below” a second element may generally be taken to signify that the first element is further from the primary illuminated surface or primary illumination source. For example, if a first element is said to be underlying a second element, the first element may be further from the sun.

It should be noted that, in various embodiments, the primary illumination source may not refer to other forms of secondary illumination, such as light returning to the device from a reflective surface located behind or beyond the device after the light originating from the primary illumination source has passed through or around the device.

Various embodiments of a back junction solar cell with selective front surface field are herein disclosed. More particularly, a back junction solar cell with selective front surface field and high-quality in situ passivation layer formed in a single anneal cycle and methods for its manufacture. These embodiments of the invention overcome one or more of the above-described disadvantages associated with previous technologies.

Embodiments of the invention provide several advantages for production of solar cells that reduce the time and cost required for their production. A solar cell of the back junction type having an emitter layer opposite an illuminated surface of the solar cell according to an example embodiment of the invention comprises a p-type emitter layer. The solar cell further comprises an n-type base layer overlying the p-type emitter layer so as to define a p-n junction at the interface of the p-type emitter layer and the n-type base layer. Additionally, the solar cell further comprises an n⁺ front surface field layer overlying the n-type base layer. Furthermore the front surface field layer comprises one or more first doped regions and one or more second doped regions. The second doped regions are more heavily doped than the first doped regions so as to form a selective front surface field.

According to another example embodiment of the invention, a method is disclosed for forming a solar cell of the back junction type. The method comprises fabricating an n-type base layer. The method may further comprise fabricating a p-type emitter layer such that the n-type base layer overlies the p-type emitter layer. Fabricating the p-type emitter layer may comprise applying a contact layer to one side of the base layer and alloying the contact layer with at least a portion of the base layer. Furthermore, fabricating the p-type emitter layer may comprise doping one or more first doped regions and one or more second doped regions so as to form an n⁺ front surface field layer such that the n⁺ front surface field layer overlies the n-type base layer. The second doped regions are more heavily doped than the first doped regions so as to form a selective front surface field.

Another example embodiment of the invention is directed to a back junction solar cell comprising a first n-type region. The solar cell further comprises a second n-type region and a third n-type region, wherein the second and third n-type regions overlie the first n-type region. Furthermore, the solar cell comprises a p-type emitter layer formed on the surface of the first n-type region opposite the second and third n-type regions. The interface of the p-type emitter layer and the first n-type region defines a p-n junction.

The above summary is provided merely for purposes of summarizing some example embodiments of the invention so as to provide a basic understanding of some aspects of the invention. Accordingly, it will be appreciated that the above described example embodiments should not be construed to narrow the scope or spirit of the invention in any way more restrictive than as defined by the specification and appended claims. It will be appreciated that the scope of the invention encompasses many potential embodiments, some of which will be further described below, in addition to those here summarized.

### BRIEF DESCRIPTION OF THE DRAWING(S)

Having thus described embodiments of the invention in general terms, reference will now be made to the accompanying drawings, which are not necessarily drawn to scale, and wherein:

FIG. 1 illustrates a cross-sectional view of a back junction solar cell in accordance with an example embodiment of the present invention; and

FIG. 2 illustrates a flowchart according to an example embodiment of a method for manufacturing a back junction solar cell of the present invention.

### DETAILED DESCRIPTION

Some embodiments of the present invention will now be described more fully hereinafter with reference to the accompanying drawings, in which some, but not all embodiments of the invention are shown. Those skilled in this art will understand that the invention may be embodied in many different forms and should not be construed as limited to the embodiments set forth herein; rather, these embodiments are provided so that this disclosure will satisfy applicable legal requirements. Like reference numerals refer to like elements throughout.

Almost all commercial crystalline silicon solar cells are currently fabricated using a p-type substrate doped with boron. Boron-doped substrates, however, suffer from light induced degradation (LID) when exposed to a light source. The loss of efficiency due to LID generally ranges from 0.2 to 0.5% absolute, or 1.2 to 2.9% relative. Substrates that are doped to be n-type, on the other hand, are immune to LID. Not only that, but n-type substrates with higher bulk lifetimes are more easily manufactured compared to p-type substrates. Furthermore, the charge carrier diffusion length for electrons differs from the charge carrier diffusion length for holes for a given dopant concentration and conductivity type. As a result, n-type substrates may produce improved charge carrier diffusion lengths in comparison to p-type substrates. For all of these reasons, n-type substrates are ideal candidates for high efficiency solar cells.

As noted above, conventional p-type solar cells are typically manufactured by n-type dopant diffusion, often using phosphorus oxychloride (POCl₃), into the front surface of the p-type substrate to create the n-type emitter layer. This results in the p-n junction forming near the front of the solar cell. Unfortunately, a comparable analog does not exist for forming a p-type emitter layer on the front surface of an n-type substrate. While boron diffusion, in the form of boron tribromide (BBr₃), may be used to form such a p-type emitter layer on an n-type substrate, doing so results in several drawbacks. Boron diffusions frequently leave a stained silicon surface because of the formation of boron-silicon compounds. Such a stain seriously degrades the appearance of the surface of the solar cell. Furthermore, removal of the boron stains requires additional and unwanted processing steps such as thermal oxidation of the stained surface followed by chemically removing the thermal oxide. Therefore, any benefit achieved by forming a p-n junction near the front surface of the n-type substrate is offset by the degradation due to boron staining and added complexity of its removal.

As an alternative, the p-n junction may be formed at the back of the n-type solar cell to create what is sometimes called a back junction solar cell. An example back junction solar cell may be formed as described in U.S. Pat. No. 6,262,359 issued Jul. 17, 2001, which is incorporated by reference as if set forth in full herein. The disclosure describes an n-type substrate with a more heavily doped n⁺ layer on the front side of the cell, which serves as a front surface field, and a p⁺ layer on the back side of the cell formed using aluminum. The n⁺ layer in these solar cells, however, may not be formed by POCl₃ diffusion as in conventional p-type solar cells due to issues related to wrap-around of the phosphorus diffusion. Alternative means, such as screen-printing phosphorus dopant or using limited source diffusion, present their own drawbacks. For example, with screen-printed phosphorus, a phosphosilicate glass grows on top of the n⁺ layer and requires removal in subsequent steps. Additionally, the screen-printed method makes further means of passivating the solar cell more difficult. For instance, using screen printed dopants may result in high surface concentration for the heavily doped diffused layer, which makes the layer less sensitive to surface passivation layers. The limited source diffusion process suffers from considerable overhead costs and a lack of sheet resistance uniformity on large area wafers. Furthermore, all of the known methods for forming an n⁺ layer in a back junction solar cell result in a uniform front surface field. The use of uniform front surface fields prevents the solar cell from reaching its potential for higher efficiencies.

The inventors have discovered a new approach to producing a back junction solar cell that solves a number of the problems described above. In particular, a back junction solar cell with a selective front surface field is described herein. The process may involve using ion implantation to dope one or more field and selective regions of the selective front surface field. In particular, the field regions are more lightly doped than the selective regions. Therefore, the field regions have a shallower junction depth and lower rate of charge carrier recombination, while the selective regions have a deeper junction depth and a lower sheet resistance to improve contacts, as is desirable. The sheet resistance of the n⁺ layer in both the field and selective regions can also be controlled more precisely. Selective front surface fields improve the spectral response of the cell in the longer wavelengths and enables higher current generation. Forming the selective front surface field occurs in a single high temperature anneal cycle, during which time oxygen may be introduced to simultaneously form a passivating oxide layer on the selective front surface field. The lighter doped field regions of the selective front surface field also enables better surface passivation, which helps increase the voltage output of the cell. The resultant solar cells may have efficiencies exceeding 18% on large area substrates.

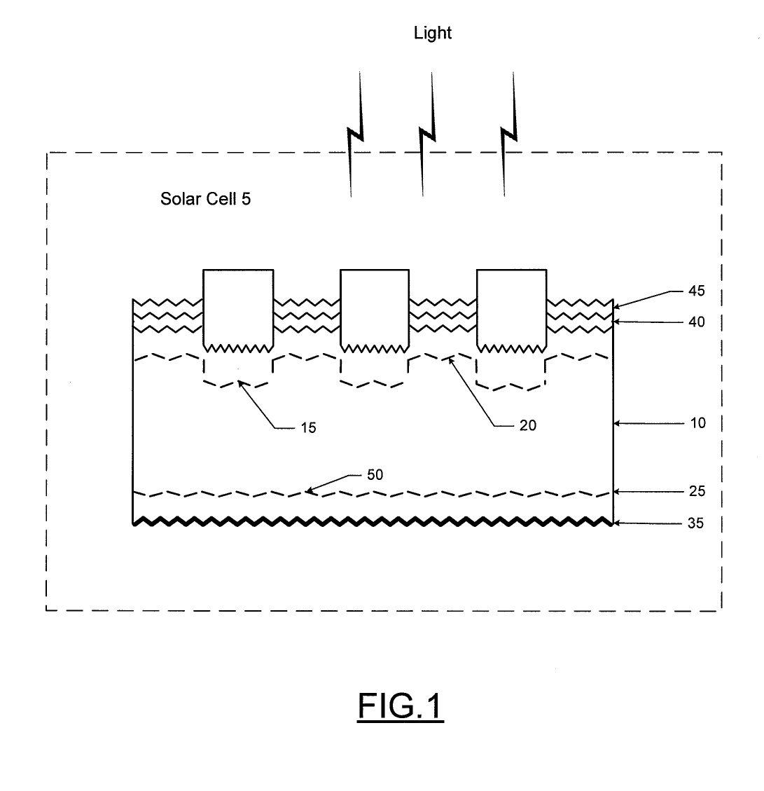

FIG. 1 illustrates one embodiment of a solar cell 5 in accordance with the present invention. The solar cell 5 may be formed of a semiconductor substrate. The substrate may be composed of silicon (Si), germanium (Ge) or silicon-germanium (SiGe) or other semiconductive material, or it may be a combination of such materials. In the case of monocrystalline substrates, the semiconductor substrate may be grown from a melt using Float Zone (FZ) or Czochralski (Cz) techniques. The resulting mono-crystalline boule may then be sawn into a wafer to form the substrate. For a substrate composed of silicon, germanium or silicon-germanium, the crystallographic orientation of the wafer surface may be (100) or (110), for example. Alternatively, the substrate can be multi-crystalline, which may be less expensive than monocrystalline substrates. However, the multi-crystalline substrate suffers from recombination of charge carriers at crystal grain boundaries, and requires passivation to avoid efficiency losses.

The front and back surfaces of the substrate may define pyramidal structures created by their treatment with a solution of potassium hydroxide (KOH) and isopropyl alcohol (IPA) during an anisotropic etching process. The presence of these structures increases the amount of light entering the solar cell 5 by reducing the amount of light that is lost by reflection from the front surface. The pyramidal structures on the back surface may be destroyed during formation of a back contact.

According to the embodiment of FIG. 1, the substrate may be doped with impurities of n-type conductivity, to create an n-type base layer 10. If the substrate is composed of silicon (Si), germanium (Ge) or silicon-germanium (Si—Ge), the n-type base layer 10 may be doped with phosphorus (P), antimony (Sb), arsenic (As) or other Group V elements to induce n-type conductivity. A selective front surface field layer made up of heavily doped selective regions 15 and lightly doped field regions 20 may be formed on the front surface of the n-type base layer 10, for example by ion implantation. The heavily doped regions 15 and lightly doped regions 20 may be doped with impurities of the same n-type conductivity as that of the n-type base layer 10, in certain embodiments the same type dopant atoms as the n-type base layer may be used.

The front surface of the doped regions 15, 20 of the selective front surface field layer and back surface of the n-type base layer 10 represent a discontinuity in their crystalline structures, and dangling chemical bonds are present at these exposed surfaces. The dangling bonds constitute recombination centers which disadvantageously annihilate charge carriers, thus lowering the efficiency of the solar cell. To prevent this from occurring, in some embodiments, oxide layers 40, 41 may be formed on both the front surface of the doped regions 15, 20 of the selective front surface field layer and the back surface of the n-type base layer 10. In doing so, a passivating oxide layer may form on the entire exposed wafer surface, including on the thin sides of the wafer that define its thickness.

The oxide layers 40, 41 may contact the front surface of the doped regions 15, of the selective front surface field layer and the back surface of the n-type base layer 10 in order to chemically satisfy the bonds of the atoms at these interfaces so that they will not annihilate charge carriers. The oxide layers 40, 41 may comprise a dielectric material such as silicon dioxide (SiO₂) for a silicon substrate, or an oxide of another semiconductor type, depending upon the composition of the substrate. The oxide layers 40, 41 may have thicknesses in a range from 5 to 150 nanometers. For example, 20 nanometers may be used. By passivating the dangling silicon bonds on the surfaces of the substrate, the oxide layers 40, 41 may reduce the surface recombination velocity and decrease the front surface field component of the reverse saturation current density (Jₒₑ), thus improving the overall efficiency of the solar cell 5. Additionally, in certain embodiments, the oxide layer 41 formed on the back surface of the n-type base layer 10 may advantageously produce a high-quality, dielectric-passivated back surface, for example when capped with a silicon nitride layer.

An antireflection layer 45 may be formed on the oxide layer 40 on the front surface of the doped regions 15, 20 of the selective front surface field layer to reduce reflection of the incident light and thus loss of solar energy. The antireflection layer 45 may have a refractive index greater than that of the oxide layer 40, which tends to cause light incident to the solar cell to refract into the antireflection layer 45 and through the oxide layer 40 to the substrate where it can be converted to free charge carriers. For example, the antireflection layer 45 may have an index of refraction in the range of 1.4 to 2.4 when measured with an incident laser having a wavelength of 632.8 nm. The antireflection layer 45 may be composed of silicon nitride (SiNₓ), aluminum oxide (Al₂O₃), titanium oxide (TiO₂), magnesium fluoride (Mg₂F), zinc oxide (ZnO), or zinc sulfide (ZnS₂), or combinations of these materials. In some embodiments, the antireflection layer 45 comprises an amorphous nitride, such as amorphous silicon nitride (a-SiNₓ). The antireflection layer 45 may have a thickness from 10 to 100 nanometers.

The front contacts 30 and front connections may be formed of conductive materials such as silver (Ag). Generally, for silicon and other substrates, silver may be used to contact the surface of the substrate that is doped n-type, such as the doped regions 15, 20 of the selective front surface field layer. Direct contact of metal to a semiconductor increases the recombination rate of electrons and holes, which can significantly lower solar cell efficiency. To decrease this effect and limit the proportion of metal covering the surface of the substrate, the front contacts 30 and front connections may be configured as point or line contacts (sometimes called “local contacts”). The spacing and arrangement of point or line contacts can be determined as described in U.S. Publication No. 2009/0025786 published Jan. 29, 2009, which is incorporated by reference as if set forth in full herein.

The front contacts 30 and front connections may be formed by screen-printing the silver on the front surface of the antireflection layer 45. The front connections may comprise solderable pads or bus bars to facilitate electrical connections to the front surface of the solar cell 5. According to example embodiments, the pattern of the front connections may be aligned with the pattern of the back connections described below.

In addition, for the front contacts 30 and front connections, silver may be selected because of its high electrical conductivity to limit shadowing effects that can lower solar cell efficiency. Various commercial silver pastes are available for this purpose, such as Heraeus SOL953, or the like. However, silver is not transparent, so it may be desirable to limit the dimensions of the front contacts 30 and front connections to point or line contacts of limited area for this additional reason. To reduce the contact resistance between the front contacts 30 and the underlying selective front surface field layer, the front contacts 30 are aligned with the heavily doped regions 15 of the selective front surface field layer. In certain embodiments, the width of the front contacts 30 may be less than the width of the heavily doped regions 15 to ensure that the front contacts 30 are entirely within the heavily doped regions 15. In accordance with certain embodiments, the oxide layer 40 and the antireflection layer 45 may be disposed on the front surface of the doped regions 15, 20 of the selective front surface field layer prior to forming the front contacts 30 and front connections. In this case, the front contacts 30 and front connections may physically penetrate the oxide layer 40 and the antireflection layer 45 to make contact with the underlying regions of the selective front surface field layer. The front contacts 30 and front connections may contain glass frit in addition to metal to facilitate their firing through the oxide layer 40 and the antireflection layer 45 to make contact with the selective front surface field layer.

The back contact 35 may be formed on the back surface of the n-type base layer 10 using screen-printed pastes. The paste used to form the back contact 35 may be an aluminum paste, such as Monocrystal Analog 12D, or the like. In some embodiments, the back contact 35 may cover nearly the entire back surface of the n-type base layer 10. Alternatively, the back contact 35 may only cover a portion of the back surface of the n-type base layer 10. In accordance with certain embodiments, the oxide layer 41 may be disposed on the back surface of the n-type base layer 10 prior to forming the back contact 35. In this case, the back contact 35 may physically penetrate the oxide layer 41 to make contact with the n-type base layer 10. The oxide layer 41 may be consumed by glass frit in the paste during formation of the back contact 35.

Due to the firing of the back contact 35, an aluminum-doped p⁺ silicon emitter layer 50 may be formed by liquid phase epitaxial regrowth at the interface of the n-type base layer 10 and the back contact 35. In these embodiments, the back contact 35 may make electrical contact with the aluminum-doped p⁺ silicon layer 50. The back contact 35 may be composed of an aluminum-silicon eutectic composition. Since the aluminum may serve as both the dopant for forming the aluminum-doped p⁺ silicon emitter layer 50 and the back contact 35, the back contact 35 may act as a self-aligning contact to the aluminum-doped p⁺ silicon emitter layer 50. The method may reduce the possibility of the back contact 35 shunting the p-n junction 25 for the same reason, namely that the aluminum of the back contact 35 is the source of the p-type dopant for forming the p-n junction 25. Additionally, the depth of the selective front surface field layer is of no real concern regarding shunting due to the location of the p-n junction 25 near the back surface of the solar cell 5.

The back contact 35 may also serve as a reflective back layer for the solar cell 5. Having a reflective back layer provides a reflective surface to return incident light reaching the back to the substrate where it can generate free charge carriers. The thickness of the back contact 35 may be from 10 to 50 micrometers in thickness and provide adequate reflectivity.

A p-n junction 25 may be formed at the interface between the n-type base layer 10 and the aluminum-doped p⁺ silicon emitter layer 50 near the back side of the solar cell 5. Because of their opposite conductivities, the n-type base layer 10 and the aluminum-doped p⁺ silicon emitter layer 50 create an electric field across the p-n junction 25 which separates free electrons and holes resulting from absorption of light photons and forces them to move in opposite directions to respective front and back contacts 30, 35.

In various embodiments, back connections such as solderable pads or bus bars may be formed on the back contact 35 to facilitate electrical connections to the back surface of the solar cell 5. The back connections may be formed on the back contact 35 by applying silver soldering pads on the back of the back contact 35, for example Ferro LF33750 polymer Ag. Alternatively, a solderless interconnect method capable of bonding directly to the aluminum back contact 35 may be used, such as Hitachi Chemical conductive film. Another alternative may involve screen-printing a lift-off paste, for example Heraeus lift-off paste. Yet another alternative is the deposition of solderable metal pads on the back aluminum surface by a plasma coating process, such as that offered by Reinhausen Plasma.

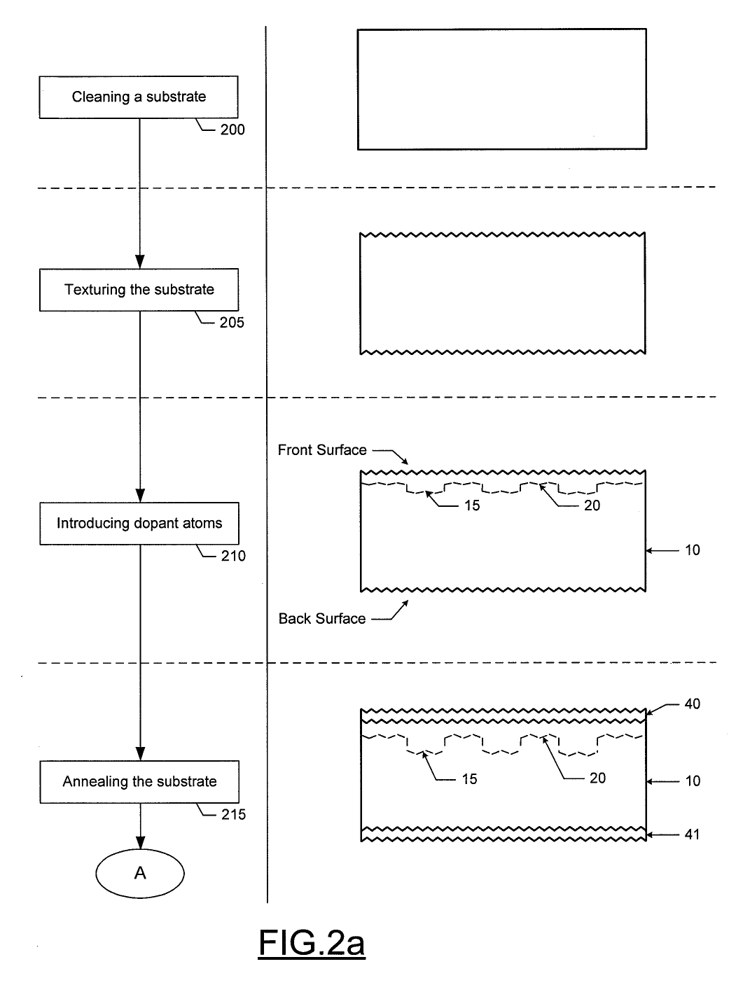

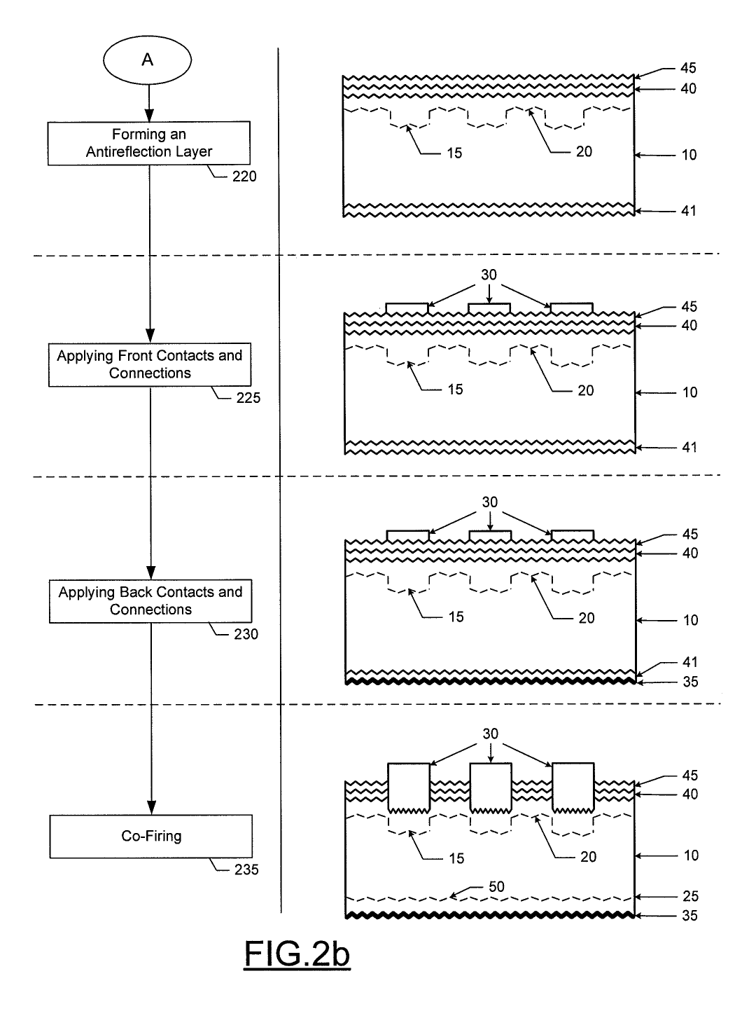

FIG. 2 illustrates a flowchart according to an example method for manufacturing another example back junction solar cell with selective front surface field and high-quality in situ passivation layer formed in a single anneal cycle according to an example embodiment of the present invention. FIG. 2 thus discloses the methods for their manufacture in accordance with the present invention.

Referring to FIG. 2 at operation 200 a substrate is provided. The substrate may be as described above with respect to FIG. 1. Normally, a substrate can be ordered from suppliers with a specified amount of n-type conductivity. According to various embodiments, the substrate may be doped with n-type dopant to form an n-type base layer 10. The dopant concentration may be in a range from 10¹³ to 10²¹ atoms per cubic centimeter (atoms/cm³). The thickness of the substrate may be in a range from 50 to 500 μm, although savings of semiconductor material can be achieved relative to current standard substrates by using substrates with a thickness from 50 to less than 200 μm. Resistivity of the substrate may be in a range from 1 to 150 Ohm-cm, with excellent results obtained using 10 to 100 Ohm-cm. Monocrystalline or multicrystalline, or possibly string ribbon, thin-film or other types of substrates, may be used.

At operation 200, the substrate may be cleaned to prepare it for processing. The cleaning may be accomplished by immersion of the substrate in a bath of potassium hydroxide (KOH) having, for example, about a 1-10% concentration, to etch away saw damage on the surfaces of the substrate. According to some example embodiments, etching may be conducted at a temperature from about 60 to 90 degrees Celsius.

At operation 205, the substrate may be textured. For example, the substrate may be textured by anisotropically etching it by immersion in a bath of potassium hydroxide and isopropyl alcohol (KOH-IPA). According to some example embodiments, the potassium hydroxide concentration may be about a 1-10% concentration, and the isopropyl alcohol may be about a 2-20% concentration. The temperature of the KOH-IPA bath may be about 65 to 90 degrees Celsius. The KOH-IPA etches the surfaces of the substrate to form pyramidal structures with faces at the crystallographic orientation. The resulting pyramidal structures help to reduce reflectivity at the front surface and to trap light within the substrate where it can be absorbed for conversion to electric energy.

At operation 210, dopant atoms may be introduced to the front surface of the n-type base layer 10. According to various embodiments, the dopant atoms may be introduced by ion implantation. The dopant atoms may have n-type conductivity like that of the n-type base layer 10. In certain embodiments, the n-type dopant may be phosphorus ions, for example P³¹⁺, or the like. According to various embodiments, patterning of the selective regions 15 and the field regions 20 may be achieved by two ion implantation steps. For example, the selective front surface field layer may be formed by performing a first ion implantation step uniformly over the front surface of the n-type base layer 10 followed by performing a second ion implantation step in just the selective regions 15. Alternatively, patterning of both fields may be achieved in a single ion implantation step. For example, a single ion implantation step may be performed where the ion implanter implants at a higher dose or uses a slower beam rate when passing over the selective regions 15.

In embodiments where two ion implantation steps are performed, the first ion implantation may be performed uniformly over the front surface of the n-type base layer 10 at a dose from about 1.0×10¹⁵ cm⁻² to 3.0×10¹⁵ cm⁻², for example 1. 7×10¹⁵ cm⁻². Beam acceleration may be performed at a range of 5 kiloelectron-volts (keV) to 30 keV, preferably 10 keV. After the one or more field regions 20 have been doped, the second ion implantation step may be performed to dope the one or more selective regions 15. Patterning of the selective regions 15 may be achieved by performing the ion implantation through a mask, for example a graphite shadow mask. The use of a superstrate shadow mask may allow the substrate to remain loaded in the ion implanter for both ion implantation steps without removal between the two steps. The graphite mask may have openings from 300 to 500 micrometers wide and having a length equal to or greater than the width of the substrate, for example 156 millimeters.

The second ion implantation step may be performed at a higher dose than the first ion implantation step, for example using a dose from about 0.7×10¹⁵ cm⁻² to 7.0×10¹⁵ cm⁻², for example 1.7×10¹⁵ cm⁻². Additionally, beam acceleration during the second ion implantation step may be performed at a range of 5 keV to 30 keV, preferably 10 keV. According to various embodiments, during the ion implantation of operation 210, one edge of the substrate, known as the reference edge, may be aligned with the edge of the mask by gravity. In alternative embodiments, the dose used during the second ion implantation step may be less than or equal to the dose of the first ion implantation step because the first ion implantation step may have already lightly doped the selective regions 15. Therefore, any dose used during the second ion implantation step that provides additional dopant to the selective regions 15 may ensure that the selective regions 15 are more heavily doped than the field regions 20.

At operation 215, the implanted substrate may be subjected to a heating step to form a selective front surface field layer. According to some embodiments, the substrate may be introduced into a furnace for annealing, for example an automated quartz tube furnace. The inner diameter of the quartz tube may be about 290 millimeters to accommodate 156 millimeter pseudosquare substrates. The annealing operation 215 may be used to accomplish several objectives at once. First, the annealing operation 215 may activate the implanted dopant ions, that is, the heat energy of the anneal operation creates vacancies in the silicon lattice for the dopant ions to fill. Second, the annealing may drive the dopant ions deeper, for example to a desired junction depth, into the substrate. Third, the annealing operation 215 may repair damage to the crystalline lattice of the substrate 10 caused by ion implantation. Fourth, the annealing operation 215 may be used to grow passivating oxide layers 40, 41 on the front surface of the doped regions 15, 20 of the selective front surface field layer and the back surface of the n-type base layer 10.

According to example embodiments, the annealing operation 215 may begin by loading 1 to 100 substrates into a furnace at a temperature in the range of 500 to 1100 degrees Celsius. In some embodiments, a large number of substrates may be simultaneously loaded into the furnace, for example up to 800 substrates may be loaded during a single furnace cycle. Once the substrates are loaded into the furnace, the temperature may be ramped up to a temperature in the range of 700 to 1100 degrees Celsius, for example from 900 to 950 degrees Celsius, over a period of 10 to 30 minutes. This temperature may then be maintained for 10 to 30 minutes, preferably 25 minutes. During this time, while the temperature is being maintained, oxygen may be introduced to the furnace, for example oxygen gas or water vapor may be introduced. The introduction of oxygen may occur for 10 to 30 minutes, preferably 10 minutes. The oxygen may be introduced at a flow rate of 100 to 5000 standard cubic centimeters per minute (sccm). The introduced oxygen may grow in situ passivating oxide layers 40, 41 on the front surface of the doped regions 15, 20 of the selective front surface field layer and the back surface of the n-type base layer 10, because the use of ion implantation rather than diffusion does not result in the formation of a glass layer that would need to be removed prior to forming an oxide layer. Finally, the temperature may be ramped down to a temperature in the range of 500 to 700 degrees Celsius over a period of 30 to 120 minutes. The substrates may then be removed from the furnace.

According to various embodiments, the ion implantation dose and energy of operation 210 along with the furnace conditions of operation 215 may affect the sheet resistances in the field regions 20 and selective regions 15. For example, operations 210 and 215 may produce a solar cell 5 with field regions 20 having a sheet resistance of 80 to 120 Ohms-per-square and selective regions 15 having a sheet resistance of 30 to 70 Ohms-per-square.

At operation 220, an antireflection layer 45 may be formed on the front passivating oxide layer 40. The antireflection layer 45 may have an index of refraction higher than the oxide layer 40 but lower than the silicon substrate, thus enabling more light to pass into the antireflection layer 45 and through the oxide layer 40 to the substrate where it can be converted to free charge carriers. The antireflection layer 45 may be composed of silicon nitride (SiNₓ), aluminum oxide (Al₂O₃), titanium oxide (TiO₂), magnesium fluoride (Mg₂F), or zinc sulfide (ZnS₂), or combinations of these materials. In certain embodiments, the antireflection layer 45 may comprise an amorphous nitride, such as amorphous silicon nitride (a-SiNₓ). The antireflection layer 45 may be formed by plasma enhanced chemical vapor deposition (PECVD). Alternatives to the PECVD process may include low pressure chemical vapor deposition (LPCVD), sputtering, and the like. The PECVD process may include heating the substrate to a temperature in the range of 400 to 450 degrees Celsius. Additionally, the PECVD process may include using silane and ammonia reactant gases. The antireflection layer 45 may have a thickness from 50 to 90 nanometers and an index of refraction of about 2.00. The thickness and index of refraction of the antireflection layer 40 may be determined by parameters such as deposition time, plasma power, flow rate of reactant gasses, and the deposition pressure.

At operation 225, the material for the front contacts 30 and front connections of the solar cell 5 may be applied to the front surface of the antireflection layer 45. According to various embodiments, the front contacts 30 and front connections may be screen-printed using a semi-automatic screen printer with optical alignment. The front contacts 30 and front connections may be applied using a silver paste, for example Heraeus SOL953 or the like. In some embodiments, the silver paste may be a fritted silver paste to help penetrate the front passivating oxide layer 40 and the antireflection layer 45 during firing of the contacts. The silver paste may be optimized specifically for forming contacts to front surface fields with low phosphorus doping. The configuration and spacing of the front contacts 30 and front connections may be defined by the contact pattern of the screen. In certain embodiments, the front contacts 30 can be 50 to 150 micrometers in width and spaced apart by 1.5 to 2.5 millimeters. The paste for the front contacts 30 and the front connections may be subsequently dried with a belt furnace. Alternatively, the front contacts 30 and front connections may be dried simultaneously with the back contact 35, as described in operation 230 below.

In various example embodiments, the pattern of the screen, such as a grid pattern, line pattern, or the like, may be designed specifically for the selective front surface field layer formed by the method described above. For example, the pattern of the front contacts 30 may be designed so that they are aligned and printed within the selective regions 15 of the selective front surface field layer. In certain embodiments, the width of the front contacts 30 may be less than the width of the selective regions 15 to ensure that the front contacts 30 are entirely within the selective regions 15. The heavy doping in these selective regions 15 also may increase the depth of the front surface field underneath, which may improve the contacts in these regions for example by improving the ability to shield carriers from the metal contacts. According to example embodiments, alignment of the front contacts 30 with the selective regions 15 of the selective front surface field layer may be accomplished through a variety of techniques known to those of ordinary skill, including optical alignment using the reference edge described above in operation 210 or another fiducial mark formed on the solar cell 5 to indicate a position relative to which alignment is to be performed, butt-edge alignment against two posts, alignment by camera to the center or edge of the substrate, or the like.

At operation 230, the material for the back contact 35 may be applied to the back surface of the n-type base layer 10. According to example embodiments, the back contact 35 may be screen-printed on the back passivating oxide layer 41 on the back surface of the n-type base layer 10. The back contact 35 may be applied using an aluminum paste, for example Monocrystal Analog 12D or the like. In certain embodiments, the aluminum paste may be screen-printed across nearly the entire back surface of the n-type base layer 10. In these embodiments, the aluminum paste of the back contact 35 may not be printed over a narrow border near the edges of the wafer approximately 1 mm wide. Alternatively, the back contacts 35 may be printed across only a portion of the back surface of the n-type base layer 10. The solar cell 5 may optionally be placed on a belt furnace at a temperature in the range of 200 to 400 degrees Celsius in air ambient for 30 to 60 seconds to dry the printed paste.

At operation 235, the substrate with the front and back contacts 30, 35 and front connections applied may be heated or co-fired in a belt furnace, such as an in-line belt furnace or the like. In the process of co-firing the structure, the front contacts 30 and front connections may fire through the front passivating oxide layer 40 and the antireflection layer 45 to form a physical connection with the doped regions 15, 20 of the selective front surface field layer. In various embodiments, the front contacts 30 may only make physical connection with the selective regions 15 of the selective front surface field layer. To facilitate firing through the oxide layer 40 and the antireflection layer 45, the front contacts 30 and front connections may contain frit, such as glass frit or the like. The glass frit in the paste used to form the front contacts 30 and front connections may melt at a temperature near 500 degrees Celsius and dissolve the underlying oxide layer 40 and antireflection layer 45. The firing temperature may be chosen such that the metal particles, such as silver, in the front contact paste form ohmic contact with the selective front surface field layer without migrating below the depth of the front surface field.

During the co-firing at operation 235, aluminum from the back contact 35 may alloy with silicon from the n-type base layer 10, for example when the temperature exceeds the aluminum-silicon eutectic temperature of 577 degrees Celsius. In some embodiments, the temperature of the furnace may be high enough during the alloying so that the aluminum may effectively dissolve silicon. When the substrate cools following the co-firing, an aluminum-doped p⁺ silicon emitter layer 50 may form on the n-type base layer 10 by liquid phase epitaxial re-growth. A p-n junction 25 may be formed at the interface of the n-type base layer 10 and the aluminum-doped p⁺ silicon emitter layer 50 to create a back junction solar cell 5. The remainder of the aluminum back contact 35 may comprise an aluminum-silicon eutectic metal layer. In certain embodiments, a portion of the back contact 35 near the back of the solar cell 5 may comprise mostly aluminum. The material of the back contact 35 may form a physical and electrical connection with the aluminum-doped p⁺ silicon emitter layer 50. In the process of co-firing the structure, the back contact 35 may fire through the back passivating oxide layer 41 to form a physical connection with the aluminum-doped p⁺ silicon emitter layer 50. As a result, the back passivating oxide layer 41 may be consumed by the back contact 35 material, for example by glass frit in the aluminum paste. The temperature profile may feature a high heating rate, in the range of 20 degrees Celsius per second to 150 degrees Celsius per second, that promotes formation of a uniform n-p⁺ interface between the textured back surface of the n-type base layer 10 and the emitter layer 50.

To facilitate a solderable connection to the back side of the solar cell 5, back connections such as solderable pads or bus bars may be formed on the back surface of the back contact 35. The back connections may be formed on the back contact 35 by applying silver soldering pads on the back of the back contact 35, for example Ferro LF33750 polymer Ag. Alternatively, a solderless interconnect method capable of bonding directly to the aluminum back contact 35 may be used, such as Hitachi Chemical conductive film. Another alternative may involve screen-printing a lift-off paste, for example Heraeus lift-off paste. Yet another alternative is the deposition of solderable metal pads on the back aluminum surface by a plasma coating process, such as that offered by Reinhausen Plasma.

The front and back connections may also become sintered, cured, or soldered to respective front and back contacts 30, 35 so that they are integrally connected and form good electrical connection to respective front and back sides of the solar cell 5. Connections may be adjoined via soldered wires to adjacent solar cells in a solar module and ultimately to a load to provide power thereto upon exposure of the solar cell to light.

According to various embodiments, and as described above, a back junction solar cell with selective front surface field may be formed. More particularly, a back junction solar cell with selective front surface field and high-quality in situ passivation layer formed in a single anneal cycle may be formed. Many advantages may be realized by forming the selective front surface field, back junction, and oxide layer(s) as described herein. For example, according to various embodiments, the selective front surface field layer and high-quality, passivating oxide layer may be formed in a single high-temperature anneal step. Additionally, according to certain embodiments, the problem of phosphosilicate glass removal and edge isolation may be solved by the processes described herein. Moreover, according to various embodiments, the solar cell 5 may comprise an n-type base layer that is immune to light induced degradation. According to various embodiments, a back junction solar cell may be produced in a single anneal step having a selective front surface field layer and passivating oxide layer with a potential cell efficiency of greater than 18% on 156 millimeter pseudosquare substrates, even with low-cost, but high-quality, screen-printed contacts. Furthermore, these improvements greatly reduce the amount of time, equipment and expense needed to produce the solar cell, and greatly increase the throughput of the manufacturing process.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of steps, elements, and/or materials than those explicitly described above are also contemplated as may be set forth in some of the appended claims. Accordingly, the specification and drawings are to be regarded in an illustrative rather than restrictive sense. Although specific terms are employed herein, they are used in a generic and descriptive sense only and not for purposes of limitation.

1. A solar cell of the back junction type having an emitter layer opposite an illuminated surface of the solar cell, the solar cell comprising:
a p-type emitter layer;
an n-type base layer overlying the p-type emitter layer so as to define a p-n junction at the interface of the p-type emitter layer and the n-type base layer; and
an n-type front surface field layer overlying the n-type base layer comprising:
one or more first doped regions, and
one or more second doped regions, wherein the second doped regions are more heavily doped than the first doped regions so as to form a selective front surface field.

2. The solar cell of claim 1 wherein the solar cell is formed from a monocrystalline Czochralski-grown silicon substrate, and wherein the n-type base layer and one or more first and second doped regions of the n-type front surface field layer are doped with phosphorus.

3. The solar cell of claim 1 wherein the p-type emitter layer comprises aluminum, and wherein the p-type emitter layer is formed by liquid phase epitaxial regrowth.

4. The solar cell of claim 1, further comprising:
a passivating oxide layer overlying the n-type front surface field layer.

5. The solar cell of claim 4, further comprising:
an antireflection layer overlying the passivating oxide layer, wherein the antireflection layer comprises an amorphous silicon nitride layer.

6. The solar cell of claim 5, further comprising:
one or more screen-printed contacts formed over the antireflection layer, wherein the one or more screen-printed contacts are in electrical communication with the more heavily doped one or more second regions of the n-type front surface field layer through the antireflection layer and the passivating oxide layer.

7. The solar cell of claim 1 wherein the one or more first doped regions and the one or more second doped regions of the n-type front surface field layer comprise implanted dopant.

8. The solar cell of claim 3, further comprising:
a self-aligning screen-printed aluminum contact formed from an aluminum paste, wherein the emitter layer and the aluminum contact are both formed from the aluminum paste, and wherein the emitter layer overlies the aluminum contact.

9. A method for forming a solar cell of the back junction type, comprising:
fabricating an n-type base layer;
fabricating a p-type emitter layer such that the n-type base layer overlies the p-type emitter layer, wherein fabricating the p-type emitter layer further comprises:
applying a contact layer to one side of the base layer, and
alloying the contact layer with at least a portion of the base layer; and
doping one or more first doped regions and one or more second doped regions so as to form an n-type front surface field layer such that the n-type front surface field layer overlies the n-type base layer, wherein the second doped regions are more heavily doped than the first doped regions so as to form a selective front surface field.

10. The method of claim 9, further comprising:
forming a passivating oxide layer over the n-type front surface field layer.

11. The method of claim 10 wherein the passivating oxide layer and the n-type front surface field layer are formed during a single anneal cycle.

12. The method of claim 10, further comprising:
depositing an amorphous silicon nitride layer over the passivating oxide layer thereby forming an antireflection coating.

13. The method of claim 12, further comprising:
screen-printing one or more front contacts on the amorphous silicon nitride layer in alignment with the more heavily doped one or more second regions of the n-type front surface field layer.

14. The method of claim 13, further comprising:
firing the one or more front contacts thereby electrically connecting the one or more front contacts with the n-type front surface field layer through the amorphous silicon nitride layer and the passivating oxide layer.

15. The method of claim 14, wherein fabricating the p-type emitter layer further comprises:
forming a contact on the surface of the p-type emitter layer such that the p-type emitter layer overlies the contact; and
wherein the p-type emitter layer comprises a p-type emitter layer formed by liquid phase epitaxial regrowth, and wherein the contact is electrically connected to the p-type emitter layer.

16. The method of claim 9 wherein the one or more first and second doped regions are formed by introducing dopant by ion implantation.

17. The method of claim 16 wherein introducing dopant to the one or more first doped regions comprises uniformly introducing dopant to the one or more first and second doped regions, and wherein introducing dopant to the one or more second doped regions comprises introducing additional dopant through a mask to the one or more second doped regions.

18. The method of claim 16 wherein introducing dopant to the one or more first and second doped regions occurs during a single ion implantation step.

19. The method of claim 17 wherein the n-type base layer is doped with phosphorus, and wherein introducing dopant to one or more first and second doped regions comprises introducing phosphorus dopant.

20. A back junction solar cell comprising:
a first n-type region;
a second n-type region;
a third n-type region, wherein the second and third n-type regions overlie the first n-type region; and
a p-type emitter layer formed on the surface of the first n-type region opposite the second and third n-type regions, wherein the interface of the p-type emitter layer and the first n-type region defines a p-n junction.
